(19) United States
(12) Patent Application Publication
(10) Pub. No.: US 2025/0226326 A1
(43) Pub. Date: Jul. 10, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Wen-Jung TSAI, Taichung City (TW); Chih-Chiang HE, Taichung City (TW); Ko-Wei CHANG, Taichung City (TW); Chien-Wei HSIEH, Taichung City (TW); Chia-Yang CHEN, Taichung City (TW)

(73) Assignee: SILICONWARE PRECISION INDUSTRIES CO., LTD., Taichung City (TW)

(21) Appl. No.: 18/903,525

(22) Filed: Oct. 1, 2024

(30) Foreign Application Priority Data
Jan. 8, 2024 (TW) 113100781

(51) Int. Cl. H01L 23/538; H01L 21/56; H01L 23/13; H01L 23/31; H01L 23/498; H01L 25/16

(52) U.S. Cl. CPC H01L 23/5385; H01L 21/56; H01L 23/13; H01L 23/3135; H01L 23/5386; H01L 25/162; H01L 23/49816

(57) ABSTRACT

An electronic package and a manufacturing method thereof are provided, in which a first carrier structure and a second carrier structure with a thickness less than that of the first carrier structure are provided, at least a first electronic component is disposed on the first carrier structure, and at least a second electronic component is disposed on the second carrier structure, wherein the first electronic component and the second electronic component are covered by an encapsulating layer, such that the second electronic component can be disposed on the second carrier structure by using a packaging module to avoid excessive height of the packaging module from occurrence.

### BACKGROUND

### 1. Technical Field

The present disclosure relates to a package structure, and more particularly, to an electronic package which can meet thinning requirements and a manufacturing method thereof.

### 2. Description of Related Art

In order to ensure the continued miniaturization and multi-functionality of electronic products and communication equipment, semiconductor packages need to develop towards miniaturization in order to facilitate the connection of multiple pins and have high functionality. In addition, as the chip computing speed becomes faster and the operating voltage becomes lower, the requirements for signal integrity and power integrity are also increasing. Therefore, the integration of the system single chip with the memory module or passive mods has become a trend.

FIG. 1 is a schematic cross-sectional view of a conventional semiconductor package 1. As shown in FIG. 1, a semiconductor package 1 comprises: a carrier structure 10, a system on a chip (SoC) 11 disposed on the carrier structure 10, a stacked chipset 12 disposed on the carrier structure 10, and an encapsulant 18 covering the SoC and the stacked chipset 12 (such as a memory module).

However, in the conventional semiconductor package 1, the SoC 11 and the stacked chipset 12 are both disposed on the same surface of the carrier structure 10, so that a height of the encapsulant 18 needs to match a height of the stacked chipset 12, resulting in difficulty in reducing a height of the semiconductor package 1 to meet the thinning requirement. At the same time, the SoC 11 cannot be exposed from the encapsulant 18, which affects the heat dissipation performance thereof.

Therefore, there is a need for a solution that addresses the aforementioned shortcomings in the prior art.

### SUMMARY

In view of the aforementioned shortcomings of the prior art, the present disclosure provides an electronic package, which comprises: a first carrier structure having a first circuit layer; a first electronic component disposed on the first carrier structure and electrically connected to the first circuit layer; a second carrier structure arranged apart from the first carrier structure and having a second circuit layer, wherein a thickness of the second carrier structure is different from a thickness of the first carrier structure; a second electronic component disposed on the second carrier structure and electrically connected to the second circuit layer; and an encapsulating layer formed on the first carrier structure and the second carrier structure to cover the first electronic component and the second electronic component, wherein the first electronic component is exposed from the encapsulating layer.

The present disclosure also provides a method of manufacturing an electronic package, which comprises: disposing on a carrier a first carrier structure with a first circuit layer and a second carrier structure with a second circuit layer spaced apart from each other, wherein a thickness of the second carrier structure is different from a thickness of the first carrier structure; disposing a first electronic component on the first carrier structure to be electrically connected to the first circuit layer, and disposing the second electronic component on the second carrier structure to be electrically connected to the second circuit layer; forming an encapsulating layer on the first carrier structure and the second carrier structure to cover the first electronic component and the second electronic component, wherein the first electronic component is exposed from the encapsulating layer; and removing the carrier.

In the aforementioned electronic package and method, a side surface of the first carrier structure and a side surface of the second carrier structure are concave-convex shape. For example, the concave-convex shaped side surface of the first carrier structure and the concave-convex shaped side surface of the second carrier structure face each other. Furthermore, convex portions of the first carrier structure and convex portions of the second carrier structure are arranged staggered with each other. Alternatively, the side surface of the first carrier structure and the side surface of the second carrier structure are in a flat form and arranged adjacent to each other.

In the aforementioned electronic package and method, the first electronic component and/or the second electronic component are partially exposed from the encapsulating layer.

In the aforementioned electronic package and method, a side surface of the encapsulating layer is flush with a side surface of the first carrier structure and/or a side surface of the second carrier structure.

In the aforementioned electronic package and method, a side surface of the first carrier structure and/or a side surface of the second carrier structure are covered by the encapsulating layer.

In the aforementioned electronic package and method, the thickness of the second carrier structure is less or greater than the thickness of the first carrier structure.

The aforementioned electronic package and method further comprise a conductive structure electrically connecting the first carrier structure and the second carrier structure. For example, the conductive structure comprises at least a conductive wire or at least a bridging component. Further, the bridge component is a bridge chip, a bridge substrate or an RDL structure.

As can be understood from the above, in the electronic package and manufacturing method thereof of the present disclosure, different carrier structures are disposed in a single package, wherein the thickness of the second carrier structure is designed to be less than the thickness of the first carrier structure, so that the second electronic component can be disposed on the second carrier structure by using a packaging module to avoid the problem of excessive height of the packaging module. Therefore, compared with the prior art, the height of the encapsulating layer of the electronic package of the present disclosure does not need to match the height of the second electronic component, such that the encapsulating layer can be thinned as required to effectively reduce the height of the electronic package, which can meet the thinning requirements of the electronic package of the present disclosure, and at the same time, the first electronic component can be exposed from the encapsulating layer to improve heat dissipation performance.

### BRIEF DESCRIPTION OF THE DRAWINGS

FIG. 1 is a schematic cross-sectional view of a conventional semiconductor package.

FIG. 2A, FIG. 2B-1 and FIG. 2C-1 are schematic cross-sectional views of a manufacturing method of an electronic package according to the present disclosure.

FIG. 2B-2 is a schematic top view of FIG. 2B-1.

FIG. 2B-3 is a schematic top view of another embodiment of FIG. 2B-2.

FIG. 2C-2 is a schematic cross-sectional view of another embodiment of FIG. 2C-1.

FIG. 3A to FIG. 3C are schematic cross-sectional views of another embodiment of an electronic package according to the present disclosure.

FIG. 4-1 to FIG. 4-3 are schematic cross-sectional views of yet another embodiment of an electronic package according to the present disclosure.

### DETAILED DESCRIPTION

Embodiments of the present disclosure are described below by examples. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “below,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

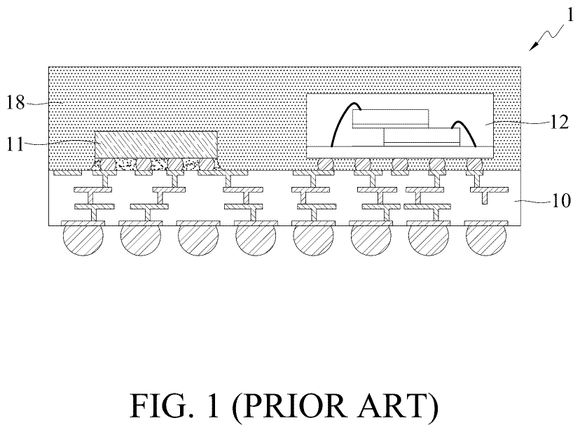

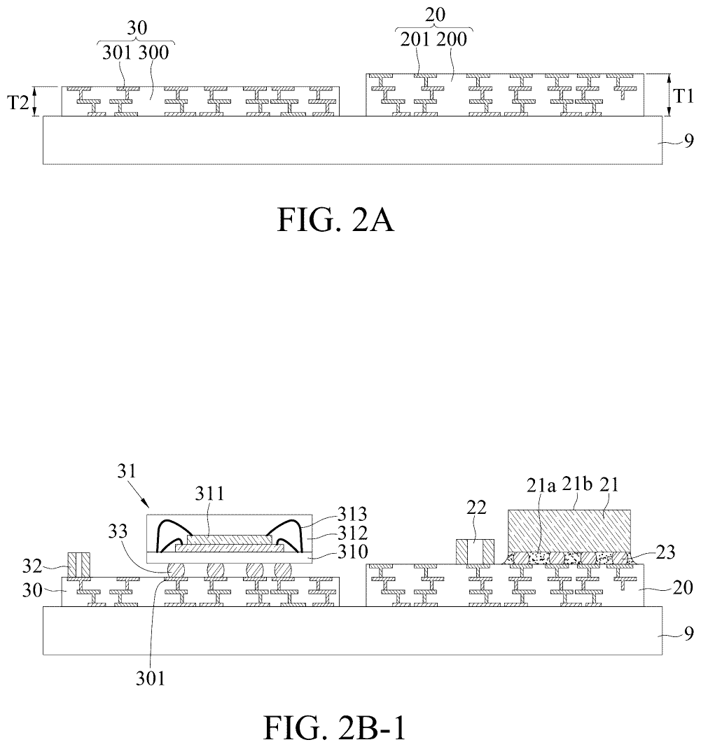

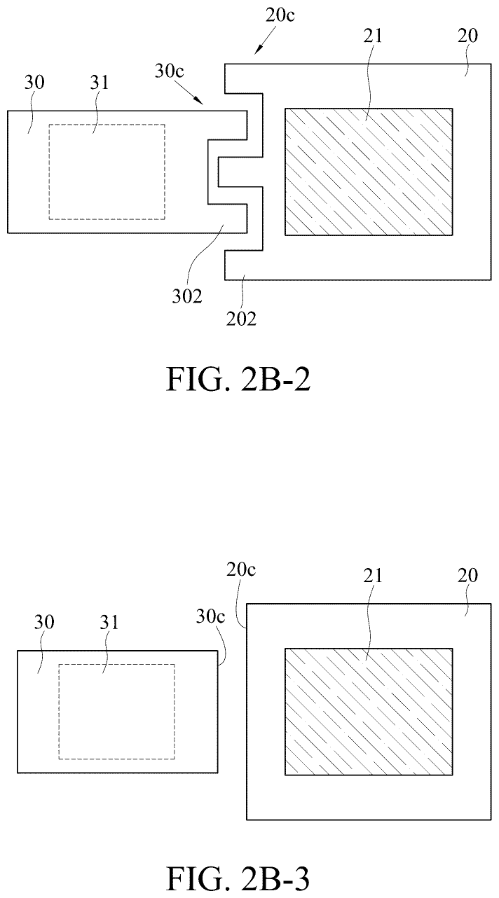

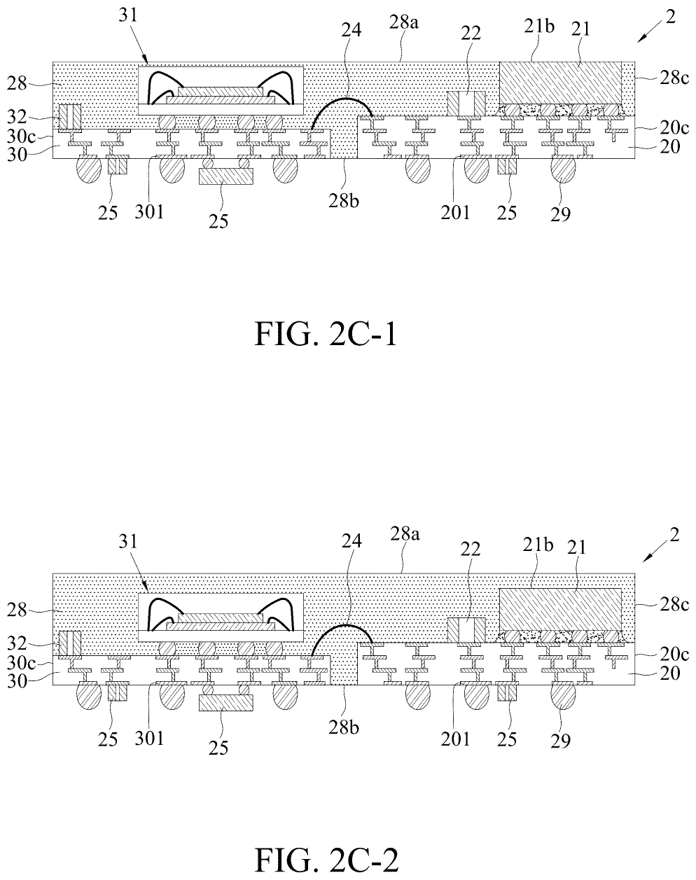

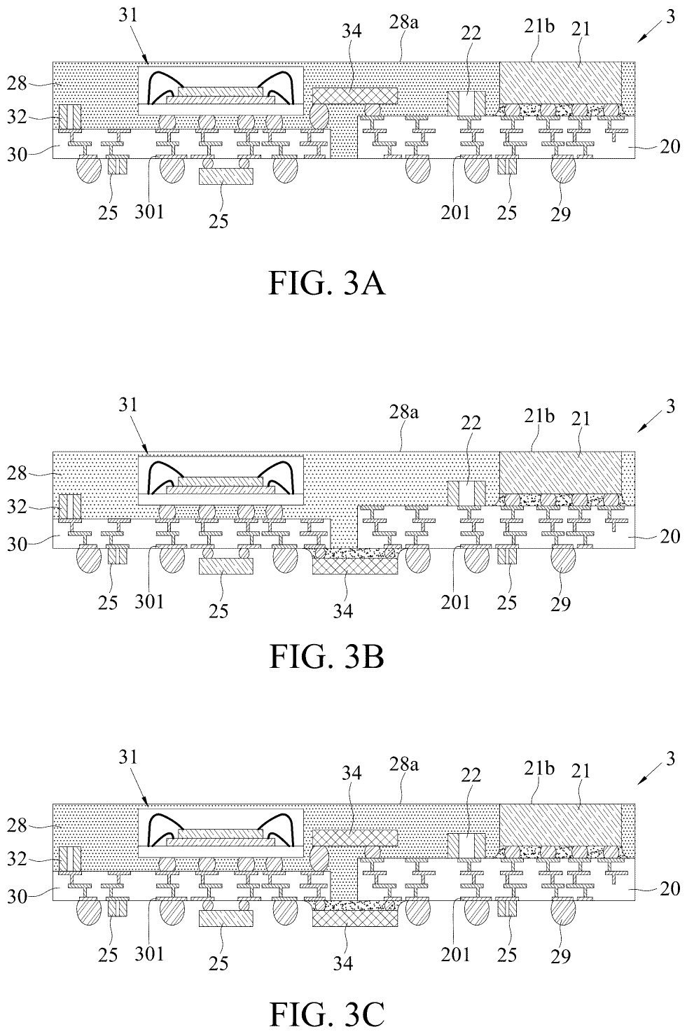

FIG. 2A, FIG. 2B-1 and FIG. 2C-1 are schematic cross-sectional views of a manufacturing method of an electronic package 2 according to the present disclosure.

As shown in FIG. 2A, at least a first carrier structure 20 and at least a second carrier structure 30 are provided, and the first carrier structure 20 and the second carrier structure 30 are disposed on a carrier 9, wherein a thickness T2 of the second carrier structure 30 is less than a thickness T1 of the first carrier structure 20.

The first carrier structure 20 is in the form of a substrate, such as a packaging substrate with a core layer and a circuit structure or a coreless circuit structure. The first carrier structure 20 includes at least a first insulating layer 200 and at least a first circuit layer 201 bonded to the first insulating layer 200, such as at least a fan-out type redistribution layer (RDL). It should be understood that the first carrier structure 20 can also be other boards that carry chips, such as a lead frame, wafer, or other carrier board with metal routing, but the present disclosure is not limited to as such.

In an embodiment, the first carrier structure 20 can be made by a number of manufacturing processes. For example, a wafer manufacturing process may be used to manufacture a circuit layer, and a chemical vapor deposition (CVD) may be used to form silicon nitride or silicon oxide as an insulating layer; alternatively, the circuit layer can be formed by using a general non-wafer manufacturing process, that is, using lower-cost polymer dielectric materials as the insulating layer, such as polyimide (PI), polybenzoxazole (PBO), prepreg (PP), molding compound, photosensitive dielectric layer or other materials formed by coating. The second carrier structure 30 is in the form of a substrate, such as a packaging

substrate with a core layer and a circuit structure or a coreless circuit structure. The second carrier structure 30 includes at least a second insulating layer 300 and at least a second circuit layer 301 bonded to the second insulating layer 300, such as at least a fan-out type redistribution layer (RDL). It should be understood that the second carrier structure 30 can also be other boards that carry chips, such as a lead frame, a wafer, or other carrier board with metal routing, but the present disclosure is not limited to as such.

In an embodiment, the second carrier structure 30 can be made by a number of manufacturing processes. For example, a wafer manufacturing process may be used to manufacture a circuit layer, and a chemical vapor deposition (CVD) may be used to form silicon nitride or silicon oxide as an insulating layer; alternatively, the circuit layer can be formed using a general non-wafer manufacturing process, that is, using lower-cost polymer dielectric materials as the insulating layer, such as polyimide (PI), polybenzoxazole (PBO), prepreg (PP), molding compound, photosensitive dielectric layer or other materials formed by coating.

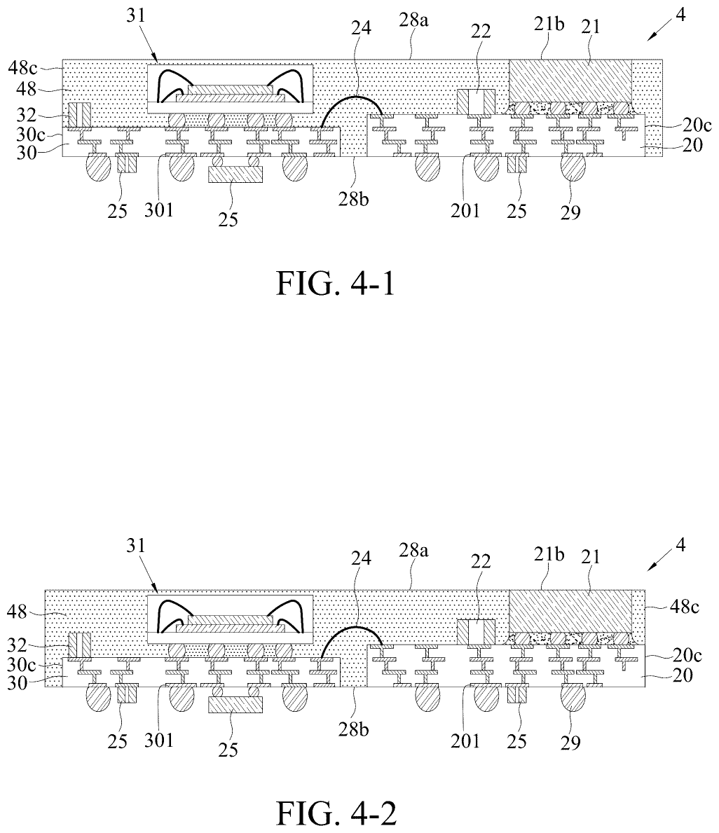

Furthermore, a side surface 20c of the first carrier structure 20 and a side surface 30c of the second carrier structure 30 are concave-convex shape. For example, the concave-convex shaped side surface 20c of the first carrier structure 20 and the concave-convex shaped side surface 30c of the second carrier structure 30 face each other, as shown in FIG. 2B-2, so that convex portions 202 of the first carrier structure 20 and convex portions 302 of the second carrier structure 30 are arranged staggered with each other to form complementary structures. In addition, in another embodiment, as shown in FIG. 2B-3, the side surface 20c of the first carrier structure 20 and the side surface 30c of the second carrier structure 30 are in a flat form and arranged adjacent to each other without concave and convex shapes.

The carrier 9 is a glass board, a wafer board or other applicable board body.

As shown in FIG. 2B-1, at least a first electronic component 21 is disposed on the first carrier structure 20 so that the first electronic component 21 is electrically connected to the first circuit layer 201, and at least a second electronic component 31 is disposed on the second carrier structure 30 so that the second electronic component 31 is electrically connected to the second circuit layer 301.

The first electronic component 21 is an active component, an inactive component or a package module, wherein the active component may be a semiconductor chip, and the inactive component may be a resistor, a capacitor, and an inductor.

In an embodiment, the first electronic component 21 is a semiconductor chip having an active surface 21a and an inactive surface 21b opposing the active surface 21a, the active surface 21a has a plurality of electrode pads (not shown), so that the electrode pads are disposed on the first carrier structure 20 by a plurality of first conductive bumps 23 in a flip-chip manner and are electrically connected to the first circuit layer 201.

Furthermore, at least a first inactive component 22 can be disposed on the first carrier structure 20.

The second electronic component 31 is an active component, an inactive component or a package module, wherein the active component may be a semiconductor chip, and the inactive component may be a resistor, a capacitor, and an inductor.

In an embodiment, the second electronic component 31 is a package module comprising a package substrate 310, at least a or a plurality of functional chips 311 disposed on the package substrate 310, and a packaging layer 312 covering the functional chip 311, and the package substrate 310 is disposed on the second carrier structure 30 and electrically connected to the second circuit layer 301 by a plurality of second conductive bumps 33. For example, the package substrate 310 is disposed with a plurality of functional chips 311 stacked on each other, and the functional chips 311 are electrically connected to the package substrate 310 by a plurality of wires 313 in a wire bonding manner. It should be understood that there are many ways for the functional chip 311 to be electrically connected to the package substrate 310, but the present disclosure is not limit to as such.

Furthermore, the packaging layer 312 is an insulating material, such as polyimide (PI), dry film, encapsulating of epoxy resin or molding compound, which can be formed on the package substrate 310 in a manner of lamination, coating or molding.

Also, at least a second inactive component 32 can be disposed on the second carrier structure 30.

As shown in FIG. 2C-1, the first carrier structure 20 and the second carrier structure 30 are electrically connected by a conductive structure 24, and then an encapsulating layer 28 is formed on the carrier 9 so that the encapsulating layer 28 covers the first carrier structure 20 and the second carrier structure 30, the first electronic component 21, the first inactive component 22, the second electronic component 31, the second inactive component 32, the first conductive bump 23 and the second conductive bump 33 and the conductive structure 24. Afterwards, the carrier 9 is removed to expose the first carrier structure 20 and the second carrier structure 30 for bonding a plurality of conductive components 29 on the first carrier structure 20 and the second carrier structure 30, and a singulation process is performed to obtain the electronic package 2. Subsequently, the electronic package 2 can be connected to an electronic device (not shown) such as a circuit board by the conductive components 29.

The conductive structure 24 comprises at least a conductive wire, such as a bonding wire, which electrically connects the first circuit layer 201 and the second circuit layer 301. In another embodiment, as an electronic package 3 shown in FIG. 3A to FIG. 3C, the conductive structure 34 may comprise at least a bridging component, such as a bridging chip, a bridging substrate or a redistribution layer (RDL) structure, and the present disclosure is not limit to as such. As further shown in FIG. 3A and FIG. 3B, in one embodiment, the conductive structure 34 can bridge over upper surfaces or lower surfaces of the first carrier structure 20 and the second carrier structure 30 to electrically connect the first circuit layer 201 and the second circuit layer 301. Or as shown in FIG. 3C, in another embodiment, a plurality of the conductive structures 34 can bridge over the upper surfaces and lower surfaces of the first carrier structure 20 and the second carrier structure 30 simultaneously, thereby electrically connecting the first circuit layer 201 and the second circuit layer 301.

The encapsulating layer 28 is an insulating layer having a first surface 28a and a second surface 28b opposing the first surface 28a, so that the second surface 28b is bonded to the carrier 9 during processing.

In an embodiment, a material forming the encapsulating layer 28 may be polyimide (PI), dry film, encapsulating of epoxy resin or molding compound. For example, the encapsulating layer 28 is formed on the carrier 9 in a manner of lamination, coating or molding. It should be understood that the material forming the encapsulating layer 28 may be the same or different from the material forming the package layer 312.

Furthermore, the second electronic component 31 and the second inactive component 32 are not exposed from the first surface 28a of the encapsulating layer 28, but partial material of the encapsulating layer 28 can be removed as required to expose the inactive surface 21b of the first electronic component 21. For example, partial material of the encapsulating layer 28 is removed by a leveling process such as grinding, so that the inactive surface 21b of the first electronic component 21 is flush with the first surface 28a of the encapsulating layer 28 (as shown in FIG. 2C-1). In addition, in another embodiment, as shown in FIG. 2C-2, the inactive surface 21b of the first electronic component 21 can also be covered by the encapsulating layer 28 and without exposing out from the encapsulating layer 28.

Also, at least a third electronic component 25 for electrically connecting the first circuit layer 201 and the second circuit layer 301 can be disposed on a side of the first carrier structure 20 and the second carrier structure 30 exposed from the encapsulating layer 28 as required. For example, the third electronic component 25 is an active component, an inactive component, or a package module, wherein the active component is such as a semiconductor chip, and the inactive component is such as a resistor, a capacitor, and an inductor.

The conductive component 29 is electrically connected to the first circuit layer 201 and the second circuit layer 301.

In an embodiment, the conductive component 29 can be a metal pillar such as a copper pillar, a metal bump covered with an insulating block, a solder ball, a solder ball with a Cu core ball, or other applicable conductive structures, but the shape is not particularly limited, for example, it can be cylinder, elliptical cylinder or polygonal cylinder.

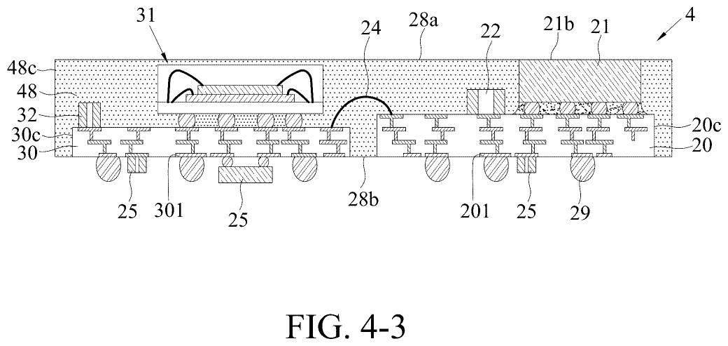

Furthermore, during the singulation process, a side surface 28c of the encapsulating layer 28 of the electronic package 2 can be flush with the side surface 20c of the first carrier structure 20 and the side surface 30c of the second carrier structure 30 (such as shown in FIG. 2C-1). Alternatively, as an electronic package 4 shown in FIG. 4-1, an encapsulating layer 48 can cover the side surface 20c of the first carrier structure 20 but expose the side surface 30c of the second carrier structure 30, so that the side surface 30c of the second carrier structure 30 is coplanar with a side surface 48c of the encapsulating 48. Alternatively, as the electronic package 4 shown in FIG. 4-2, the encapsulating layer 48 can cover the side surface 30c of the second carrier structure 30 but expose the side surface 20c of the first carrier structure 20, so that the side surface 20c of the first carrier structure 20 is coplanar with the side surface 48c of the encapsulating layer 48. Alternatively, as the electronic package 4 shown in FIG. 4-3, the encapsulating layer 48 can cover the side surface 20c of the first carrier structure 20 and the side surface 30c of the second carrier structure 30 simultaneously.

Therefore, in the manufacturing method of the electronic packages 2, 3, and 4 according to the present disclosure, different carrier structures are mainly provided in the same package to connect different electronic components, for example, by providing the second carrier structure 30 with a thinner thickness T2, the second carrier structure 30 is allowed to be disposed with the second electronic component 31 as a package module thereon. Therefore, compared with the prior art, the height of the encapsulating layer 28 of the present disclosure does not need to match the height of the second electronic component 31, so as to thin the encapsulating layer 28 as required (for example, exposing the inactive surface 21b of the first electronic component 21), thereby effectively reducing the height of the electronic packages 2, 3, and 4. Thus, the electronic packages 2, 3 and 4 of the present disclosure can be effectively thinned to comply with the development trend of being light, thin, and compact.

an electronic package 2, 3, 4 is also provided, which comprises: a first carrier structure 20 with a first circuit layer 201, a first electronic component 21, a second carrier structure 30 with a second circuit layer 301, a second electronic component 31, and an encapsulating layer 28.

The first electronic component 21 is disposed on the first carrier structure 20 and is electrically connected to the first circuit layer 201.

The second carrier structure 30 is arranged apart from the first carrier structure 20, wherein a thickness T2 of the second carrier structure 30 is smaller than a thickness T1 of the first carrier structure 20.

The second electronic component 31 is disposed on the second carrier structure 30 and is electrically connected to the second circuit layer 301.

The encapsulating layer 28 is formed on the first carrier structure 20 and the second carrier structure 30 to cover the first electronic component 21 and the second electronic component 31.

In one embodiment, a side surface 20c of the first carrier structure 20 and a side surface 30c of the second carrier structure 30 are concave-convex shape. For example, the concave-convex shaped side surface 20c of the first carrier structure 20 and the concave-convex shaped side surface 30c of the second carrier structure 30 face each other. Further, the convex portions 202 of the first carrier structure 20 and convex portions 302 of the second carrier structure 30 are arranged staggered with each other. In another embodiment, the side surface 20c of the first carrier structure 20 and the side surface 30c of the second carrier structure 30 are in a flat form.

In one embodiment, a first surface 28a of the encapsulating layer 28 is flush with a surface (i.e., inactive surface 21b) of the first electronic component 21. In another embodiment, the first electronic component 21 and the second electronic component 31 are covered by the first surface 28a of the encapsulating layer 28.

In one embodiment, a side surface 28c of the encapsulating layer 28 is flush with the side surface 20c of the first carrier structure 20 and/or the side surface 30c of the second carrier structure 30.

In one embodiment, the encapsulating layer 48 covers the side surface 20c of the first carrier structure 20 and/or the side surface 30c of the second carrier structure 30.

In one embodiment, the electronic package 2, 3, 4 further comprises a conductive structure 24, 34 electrically connecting the first carrier structure 20 and the second carrier structure 30. For example, the conductive structure 24, 34 comprises at least a conductive wire or at least a bridging component. Further, the bridging component is a bridge chip, a bridge substrate or a redistribution line layer (RDL) structure.

In view of the above, in the electronic package and manufacturing method thereof of the present disclosure, different carrier structures are mainly disposed in a single package, wherein the thickness of the second carrier structure is designed to be less than the thickness of the first carrier structure, allowing the second electronic component to be disposed on the second carrier structure by using a packaging module to avoid the problem of excessive height of the packaging module. Therefore, compared with the prior art, the height of the encapsulating layer of the electronic package of the present disclosure does not need to match the height of the second electronic component, such that the encapsulating layer can be thinned as required to effectively reduce the height of the electronic package, which can meet the thinning requirements of the electronic package of the present disclosure. Furthermore, the first electronic component can be exposed from the encapsulating layer to improve heat dissipation performance.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a first carrier structure having a first circuit layer;
a first electronic component disposed on the first carrier structure and electrically connected to the first circuit layer;
a second carrier structure arranged apart from the first carrier structure and having a second circuit layer, wherein a thickness of the second carrier structure is different from a thickness of the first carrier structure;
a second electronic component disposed on the second carrier structure and electrically connected to the second circuit layer; and
an encapsulating layer formed on the first carrier structure and the second carrier structure to cover the first electronic component and the second electronic component.

2. The electronic package of claim 1, wherein a side surface of the first carrier structure and a side surface of the second carrier structure are concave-convex shape.

3. The electronic package of claim 2, wherein the concave-convex shaped side surface of the first carrier structure and the concave-convex shaped side surface of the second carrier structure face each other and are arranged staggered with each other.

4. The electronic package of claim 1, wherein a side surface of the first carrier structure and a side surface of the second carrier structure are in a flat form and arranged adjacent to each other.

5. The electronic package of claim 1, wherein a side surface of the encapsulating layer is flush with a side surface of the first carrier structure and/or a side surface of the second carrier structure.

6. The electronic package of claim 1, wherein a side surface of the first carrier structure and/or a side surface of the second carrier structure are covered by the encapsulating layer.

7. The electronic package of claim 1, further comprising a conductive structure electrically connecting the first carrier structure and the second carrier structure.

8. The electronic package of claim 7, wherein the conductive structure comprises at least a conductive wire or at least a bridging component.

9. The electronic package of claim 8, wherein the bridge component is a bridge chip, a bridge substrate or an RDL structure.

10. The electronic package of claim 1, wherein the thickness of the second carrier structure is less or greater than the thickness of the first carrier structure.

11. The electronic package of claim 1, wherein the first electronic component and/or a second electronic component are partially exposed from the encapsulating layer.

12. A method of manufacturing an electronic package, the method comprising:
disposing on a carrier a first carrier structure with a first circuit layer and a second carrier structure with a second circuit layer spaced apart from each other, wherein a thickness of the second carrier structure is different from a thickness of the first carrier structure;
disposing a first electronic component on the first carrier structure to be electrically connected to the first circuit layer, and disposing the second electronic component on the second carrier structure to be electrically connected to the second circuit layer;
forming an encapsulating layer on the first carrier structure and the second carrier structure to cover the first electronic component and the second electronic component; and
removing the carrier.

13. The method of claim 12, wherein a side surface of the first carrier structure and a side surface of the second carrier structure are concave-convex shape.

14. The method of claim 13, wherein the concave-convex shaped side surface of the first carrier structure and the concave-convex shaped side surface of the second carrier structure face each other and are arranged staggered with each other.

15. The method of claim 12, wherein a side surface of the first carrier structure and a side surface of the second carrier structure are in a flat form and arranged adjacent to each other.

16. The method of claim 12, wherein a side surface of the encapsulating layer is flush with a side surface of the first carrier structure and/or a side surface of the second carrier structure.

17. The method of claim 12, wherein a side surface of the first carrier structure and/or a side surface of the second carrier structure are covered by the encapsulating layer.

18. The method of claim 12, further comprising a conductive structure electrically connecting the first carrier structure and the second carrier structure.

19. The method of claim 18, wherein the conductive structure comprises at least a conductive wire or at least a bridging component.

20. The method of claim 19, wherein the bridge component is a bridge chip, a bridge substrate or an RDL structure.

21. The method of claim 12, wherein the thickness of the second carrier structure is less or greater than the thickness of the first carrier structure.

22. The method of claim 12, wherein the first electronic component and/or a second electronic component are partially exposed from the encapsulating layer.
